(19) United States
(12) Patent Application Publication
(10) Pub. No.: US 2026/0308741 A1
(43) Pub. Date: Oct. 8, 2026

(54) HIGH-PRESSURE SUBSTRATE PROCESSING APPARATUS

(71) Applicant: HPSP Co., Ltd., Hwaseong-si, Gyeonggi-do (KR)

(72) Inventor: Chul Hee SHIN, Hwaseong-si, Gyeonggi-do (KR)

(21) Appl. No.: 19/482,351

(22) PCT Filed: Apr. 24, 2024
(86) PCT No.: PCT/KR2024/005549

§ 371 Date: Nov. 7, 2025

(30) Foreign Application Priority Data
May 9, 2023 (KR) 10-2023-0059644

(51) Int. Cl. C23C 8/06

(52) U.S. Cl. CPC C23C 8/06

(57) ABSTRACT

The present invention provides a high-pressure substrate processing apparatus comprising: an inner chamber having a reaction space in which a substrate to be processed is disposed; an outer chamber disposed so as to contain the inner chamber; a gas supply module configured to supply a reaction gas for processing the substrate to be processed to the reaction space at a first pressure higher than the atmospheric pressure, and to supply a protective gas to a protective space between the outer chamber and the inner chamber at a second pressure configured in relation to the first pressure; a rotational driving module comprising a power generating unit for generating rotational power, a power transfer unit formed to transfer the rotational power to the substrate to be processed such that the substrate to be processed is rotated, and a sealing unit for sealing the gap between the inner chamber and the power transfer unit, the sealing unit being affected by the pressure difference between the first and second pressures; and a control module configured to control the gas supply module so as to maintain the pressure difference between the first and second pressures to be smaller than a maximum allowable pressure difference of the sealing unit.

### DESCRIPTION

### Technical Field

The present disclosure relates to a processing apparatus used to process a substrate in a high-pressure environment.

### Background Art

Generally, during the semiconductor device manufacturing process, various types of processing are performed on a semiconductor substrate. Examples of the processing include oxidation, nitridation, deposition, ion implantation, etc. A hydrogen or deuterium heat treatment process is also used to improve the interface characteristics of the semiconductor device.

During these processes, the semiconductor substrate rotates to improve the uniformity of gas and heat distribution across the semiconductor substrate. The substrate rotation is utilized when the process pressure is low pressure (vacuum).

In the high-pressure environment, the large pressure difference between the inside and outside of the chamber prevents the semiconductor substrate from rotating. This is because the configuration for rotating the semiconductor substrate entails the high risk of high-pressure gas leakage to the outside of the chamber.

The above-described background art is technical information retained by the inventor to derive the embodiments of the present disclosure or acquired by the inventor while deriving the present disclosure, and thus should not be construed as art that was publicly known prior to the filing date of the present disclosure.

### DISCLOSURE

### Technical Problem

The present disclosure is to provide a high-pressure substrate processing apparatus capable of stably rotating a semiconductor substrate even at pressures higher than atmospheric pressure within a chamber.

### Technical Solution

According to an aspect of the present disclosure, a high-pressure substrate processing apparatus includes: an inner chamber having a reaction space in which a substrate to be processed is disposed; an outer chamber disposed so as to accommodate the inner chamber; a gas supply module configured to supply a reaction gas for processing the substrate to be processed to the reaction space at a first pressure higher than the atmospheric pressure, and to supply a protective gas to a protective space between the outer chamber and the inner chamber at a second pressure set in relation to the first pressure; a rotational driving module including a power generating unit for generating rotational power, a power transmission unit formed to transmit the rotational power to the substrate to be processed such that the substrate to be processed rotates, and a sealing unit for sealing a gap between the inner chamber and the power transmission unit, the sealing unit being affected by a pressure difference between the first and second pressures; and a control module configured to control the gas supply module so as to maintain the pressure difference between the first and second pressures to be smaller than a maximum allowable pressure difference of the sealing unit.

The control module may operate to reduce the pressure difference between the first and second pressures when the pressure difference between the first and second pressures exceeds a reference pressure difference smaller than the maximum allowable pressure difference.

The high-pressure substrate processing apparatus may further include: a gas exhaust module configured to exhaust the reaction gas from the reaction space and the protective gas from the protective space, in which the control module may operate at least one of the gas supply module and the gas exhaust module to reduce the pressure difference between the first and second pressures.

When power is cut off, the control module may allow communication between the reaction space and the protective space to eliminate the pressure difference between the first and second pressures.

The control module may control the power generating unit so that a magnitude of the rotational power varies depending on a magnitude of the first pressure.

The inner chamber may further include: an inner housing; and an inner door defining the reaction space together with the inner housing, and the control module may control the rotational driving module so that a boat rotates during movement of the inner door away from the inner housing.

The first pressure may range from a few to several tens of atm, and the second pressure may be greater than the atmospheric pressure.

According to another aspect of the present disclosure, a high-pressure substrate processing apparatus includes: an inner chamber having a reaction space in which a substrate to be processed is disposed; an outer chamber disposed so as to accommodate the inner chamber; a gas supply module configured to supply a reaction gas for processing the substrate to be processed to the reaction space at a first pressure higher than the atmospheric pressure, and to supply a protective gas to a protective space between the outer chamber and the inner chamber at a second pressure set in relation to the first pressure; and a rotational driving module extending from the protective space into the reaction space, affected by a pressure difference between the first and second pressures, and configured to rotate and drive the substrate to be processed disposed in the reaction space.

The inner chamber may further include a boat disposed in the reaction space and onto which the substrate to be processed is loaded, and the rotational driving module may include: a power generating unit disposed in the protective space and configured to generate rotational power; and a power transmission unit linking the power generating unit to the boat to allow the boat to rotate by receiving the rotational power.

The power generating unit may include a motor-driven actuator, and the power transmission unit may include a transmission shaft connected to the power generating unit and penetrating through the inner chamber to be coupled to the boat.

The rotational driving module may further include a sealing unit that seals a gap between the power transmission unit and the inner chamber, and the sealing unit may have a maximum allowable pressure difference greater than the pressure difference between the first and second pressures.

The inner chamber may further include: an inner housing forming the reaction space; and an inner door configured to open and close the reaction space, and the rotational driving module is mounted on the inner door.

The outer chamber may include an outer door positioned to face the inner door, and the rotational driving module may be disposed spaced apart from the outer door to allow the outer door to move toward the inner door.

### Advantageous Effects

According to the high-pressure substrate processing apparatus of the present disclosure configured as described above, a rotational driving module is provided to rotate a boat disposed in an inner chamber, relative to the inner chamber having a first pressure higher than atmospheric pressure and an outer chamber having a second pressure, and a control module maintains a pressure difference between the first and second pressures smaller than the maximum allowable pressure difference of the sealing unit of the rotational driving module. Therefore, even in the high-pressure environment, the semiconductor substrate may stably rotate while maintaining the pressure difference between the first and second pressures.

As a result, by increasing the uniformity of gas and heat distribution across the semiconductor substrate, it is possible to further improve the quality of high-pressure processing for the semiconductor substrate.

### [BRIEF DESCRIPTION OF THE DRAWINGS]

FIG. 1 is a conceptual diagram of a high-pressure substrate processing apparatus 100 according to an embodiment of the present disclosure.

FIG. 2 is a cross-sectional view illustrating a state where the high-pressure substrate processing apparatus 100 of FIG. 1 is closed.

FIG. 3 is a cross-sectional view illustrating a state where the high-pressure substrate processing apparatus 100 of FIG. 2 is open.

FIG. 4 is a block diagram illustrating a control configuration of the high-pressure substrate processing apparatus 100 of FIG. 1.

FIG. 5 is a flowchart for describing an operation of the high-pressure substrate processing apparatus 100 according to another embodiment of the present disclosure.

FIG. 6 is a flowchart for describing the operation of the high-pressure substrate processing apparatus 100 according to another embodiment of the present disclosure.

### BEST MODE

Hereinafter, exemplary embodiments of the present disclosure will be described in detail with reference to the accompanying drawings.

The present disclosure is not limited to exemplary embodiments set forth herein, but may be modified in various different forms. However, the present embodiment is provided solely to ensure that the disclosure of the present disclosure is complete and to fully inform those skilled in the art of the scope of the invention. Therefore, the present disclosure is not limited to the embodiments disclosed below, but should be understood to encompass all modifications, equivalents, and substitutions within the teachings and scope of the present disclosure, including substitutions or additions of components of one embodiment with those of another.

It should be understood that the accompanying drawings are provided only in order to allow embodiments disclosed in the present specification to be easily understood, and the teachings disclosed in the present specification are not limited by the accompanying drawings, but includes all the modifications, equivalents, and substitutions included in the teachings and the scope of the present disclosure. In the drawings, components may be exaggerated in size or thickness for ease of understanding, but this should not be construed as limiting the scope of protection of the present disclosure.

Terms used in the present specification are used only in order to describe specific implementation examples or embodiments rather than limiting the present disclosure. Singular expressions are intended to include plural expressions unless the context clearly indicates otherwise. In the specification, terms such as “~comprising,” or “~consisting of” are intended to specify the presence of stated features, numbers, steps, operations, components, parts, or combinations thereof described in the specification. That is, it should be understood that terms such as “~including” or “~consisting of” in the specification do not preclude the existence or addition possibility of one or more other features or numbers, steps, operations, components, parts, or combinations thereof.

Terms including ordinal numbers such as “first”, “second”, etc., may be used to describe various components, but the components are not to be construed as being limited to the terms. The terms are used to distinguish one component from another component.

It is to be understood that when one element is referred to as being “connected to” or “coupled to” another element, it may be connected directly to or coupled directly to another element or be connected to or coupled to another element, having the other element intervening therebetween. On the other hand, it should be understood that when one element is referred to as being “connected directly to” or “coupled directly to” another element, it may be connected to or coupled to another element without the other element interposed therebetween.

When a component is referred to as being “above” or “below” another component, it should be understood that it is not only positioned directly above that other component, but also that other components may be present in between.

Unless indicated otherwise, it is to be understood that all the terms used in the specification including technical and scientific terms have the same meaning as those that are generally understood by those who skilled in the art. It should be understood that the terms defined by the dictionary are identical with the meanings within the context of the related art, and they should not be ideally or excessively formally defined unless the context clearly dictates otherwise.

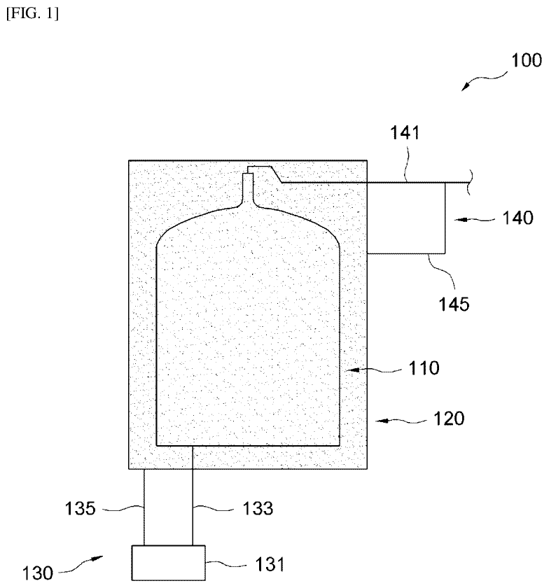

FIG. 1 is a conceptual diagram of a high-pressure substrate processing apparatus 100 according to an embodiment of the present disclosure.

Referring to this drawing, a high-pressure substrate processing apparatus 100 may include an inner chamber 110, an outer chamber 120, a gas supply module 130, and a gas exhaust module 140.

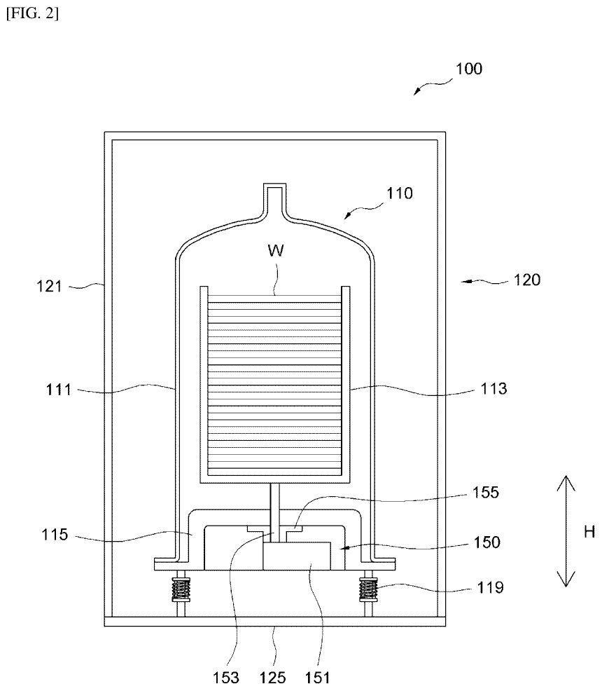

The inner chamber 110 forms a reaction space that accommodates a substrate to be processed. The inner chamber 110 may be manufactured from a non-metallic material, such as quartz, to reduce contamination in a high-temperature and high-pressure operating environment. Depending on an operation of a heater (not illustrated) disposed on an outer side of the inner chamber 110, the temperature of the inner chamber 110 may reach several hundred to a thousand ° C. The substrate may be, for example, a semiconductor substrate W (see FIG. 2) loaded onto a holder. The holder may be a wafer boat 113 (see FIG. 2) capable of loading a substrate to be processed W in multiple layers. The substrate is not limited to the wafer, and any other base structures for forming a circuit may also be used. For example, the substrate may also include glass for display manufacturing.

The outer chamber 120 is disposed to accommodate the inner chamber 110. Unlike the inner chamber 110, the outer chamber 120 is free from concerns about contamination of the object, and thus may be made of metal. The outer chamber 120 has a hollow shape having an inner space that accommodates the inner chamber 110.

The gas supply module 130 is configured to supply gas to the inner chamber 110 and the outer chamber 120. The gas supply module 130 has a gas supply device 131 that serves as a gas source. The gas supply device 131 may selectively supply, to the inner chamber 110, reaction gases, such as hydrogen gas (H₂), deuterium gas (D₂), fluorine gas (F₂), ammonia gas (NH₃), chlorine gas (Cl₂), and nitrogen gas (N₂) as a reaction gas for heat treatment. The gas supply device 131 may provide, to the outer chamber 120, a protective gas, such as nitrogen gas or argon gas (Ar) that is the inert gas. The reaction gas and the protective gas are injected into the inner chamber 110 or the outer chamber 120 through a reaction gas line 133 or a protective gas line 135, respectively. The protective gas injected into the outer chamber 120 is supplied to a space (protective space) between the outer chamber 120 and the inner chamber 110. Specifically, the protective space is an area of the inner space excluding the space occupied by the inner chamber 110.

The reaction gas and the protective gas may be supplied to form a pressure higher than atmospheric pressure (high pressure), for example, ranging from a few to several tens of atm. When the pressure of the reaction gas is a first pressure and the pressure of the protective gas is a second pressure, the first and second pressures may be maintained at a set relationship (range). For example, the second pressure may be set to be slightly higher than the first pressure. Such a pressure difference provides the advantage of preventing the reaction gas from leaking from the inner chamber 110 and preventing damage to the inner chamber 110 due to the first pressure.

The gas exhaust module 140 is configured to exhaust the reaction gas and the protective gas. To exhaust the reaction gas from the inner chamber 110, an exhaust pipe 141 is connected to an upper portion of the inner chamber 110. Similarly, to exhaust the protective gas from the outer chamber 120, an exhaust pipe 145 communicating with the outer chamber 120 may be provided. Since these exhaust pipes 141 and 145 are integrated into one, the reaction gas is diluted in the protective gas during the exhaust process, so the concentration of the reaction gas is lowered.

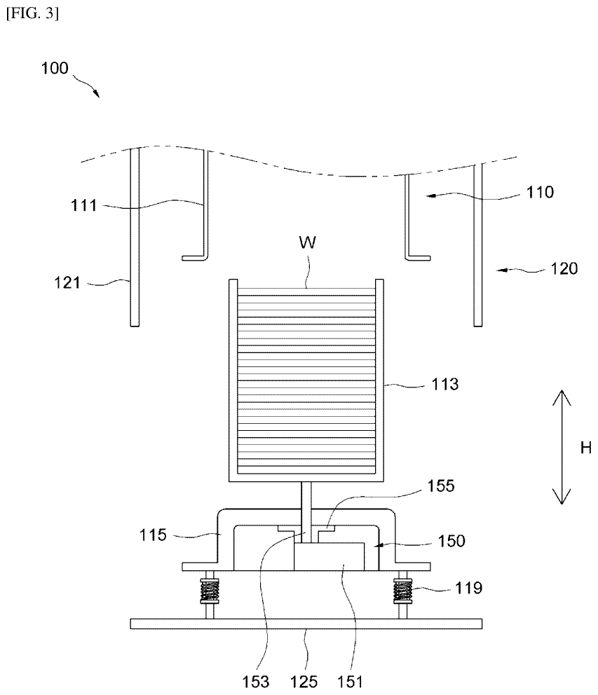

FIG. 2 is a cross-sectional view illustrating a state where the high-pressure substrate processing apparatus 100 of FIG. 1 is closed, and FIG. 3 is a cross-sectional view illustrating a state where the high-pressure substrate processing apparatus 100 of FIG. 2 is open. In FIGS. 2 and 3, some components, such as the gas supply module 130 of FIG. 1, are omitted for simplicity.

Referring to these drawings, the inner chamber 110 includes an inner housing 111 and an inner door 115. The inner housing 111 has the form in which a lower portion of the inner housing 111 is open. The inner door 115 has a form that closes the open lower portion of the inner housing 111. The inner housing 111 and the inner door 115 define the reaction space together. The inner door 115 may have a trough shape with an open bottom overall.

As the inner door 115 moves, for example, moves down, the reaction space opens (open state, see FIG. 3). In the open state, the inner door 115 is separated from the inner housing 111. As the inner door 115 moves in the opposite direction, for example, moves up, the reaction space is closed (closed state, see FIG. 2). In the closed state, the inner door 115 is in contact with the inner housing 111. In the open state, the substrate to be processed is unloaded from the boat 113, and a new substrate to be processed is loaded onto the boat 113.

The outer chamber 120 also includes an outer housing 121 and an outer door 125. The outer housing 121 is sized to accommodate the inner chamber 110. The inner housing 111 is mounted on the outer housing 121. The outer door 125 may also open and close the outer housing 121 as the outer door 125 moves. The outer door 125 is connected to the inner door 115 by a support member 119. The support member 119 has a spring support structure that elastically expands and contracts along an opening/closing direction H. When the outer housing 121 is upright, the opening/closing direction H refers to a vertical direction. During the transition from the open state to the closed state, the support member 119 allows the outer door 125 to move toward the inner door 115.

The outer door 125 opens and closes the outer housing 121 while moving up and down together with the inner door 115. Unlike the above description, the inner door 115 and the outer door 125 are not connected to each other and may be open and closed independently.

The outer door 125 also moves between the open state and the closed state, similar to the inner door 115. In the open state, the outer door 125 is positioned spaced apart from the outer housing 121. In the closed state, the outer door 125 comes into contact with the outer housing 121. The outer door 125, the inner door 115, and the boat 113 move along a linear path by a lifter (not illustrated). This linear path follows the opening/closing direction H.

A rotational driving module 150 is additionally provided to rotate the substrate W to be processed. As the substrate W to be processed rotates, the uniformity of gas/heat distribution across the substrate W to be processed increases. The uniformity improves the quality of various processing operations, such as deposition and heat treatment, performed on the substrate W to be processed. The rotational driving module 150 may operate not only when the substrate W to be processed is positioned in the reaction space, but also when the substrate W to be processed moves away from the reaction space. In this case, the substrate W to be processed may be cooled more uniformly during the cooling process following the processing operation.

The rotational driving module 150 operates in an environment where a difference occurs between the first and second pressures. The rotational driving module 150 is also configured to operate while maintaining a pressure difference between the first and second pressures. The rotational driving module 150 may extend from the outer chamber 120 into the inner chamber 110.

The rotational driving module 150 may specifically include a power generating unit 151, a power transmission unit 153, and a sealing unit 155.

The power generating unit 151 generates rotational power and may be disposed in the protective space. The power generating unit 151 may include, for example, a motor-driven actuator. The motor-driven actuator may include an electric motor (not illustrated) and a reducer (not illustrated) connected to the electric motor. A cable (not illustrated) connected to the electric motor may penetrate through the outer door 125.

The power transmission unit 153 is a component that links the power generating unit 151 and the boat 113 to allow the boat 113 to receive the rotational power and rotate. The power transmission unit 153 may be, for example, a transmission shaft connected to the power generating unit 151. The transmission shaft may be disposed to penetrate through the inner chamber 110, specifically the inner door 115. The transmission shaft is coupled to the boat 113.

The sealing unit 155 is a component that seals a gap between the inner chamber 110 and the power transmission unit 153. Specifically, the sealing unit 155 maintains the pressure difference between the first and second pressures despite the gap between the inner door 115 and the power transmission unit 153. To this end, the sealing unit 155 has a maximum allowable pressure difference higher than the pressure difference between the first and second pressures by which the sealing unit 155 is affected. For example, when the maximum allowable pressure difference of the sealing unit 155 is 14 psi, the pressure difference between the first and second pressures is maintained to be smaller than 14 psi.

In addition to the sealing unit 155 and the power transmission unit 153, the power generating unit 151 may also be mounted in the inner chamber 110, specifically, in the inner door 115. The power transmission unit 153 is disposed to penetrate through the inner door 115, and the sealing unit 155 may be coupled to the inner door 115. The power transmission unit 153 is also disposed to penetrate through the sealing unit 155. The power generating unit 151 is coupled to the sealing unit 155, and thus, is coupled to the inner door 115.

By virtue of such a coupling structure, the rotational driving module 150 is spaced apart from the outer door 125. The power generating unit 151, which is positioned at the lowermost position, is also spaced apart from an upper surface of the outer door 125. This structure does not restrict the relative movement between the outer door 125 and the inner door 115 due to the spring action of the support member 119.

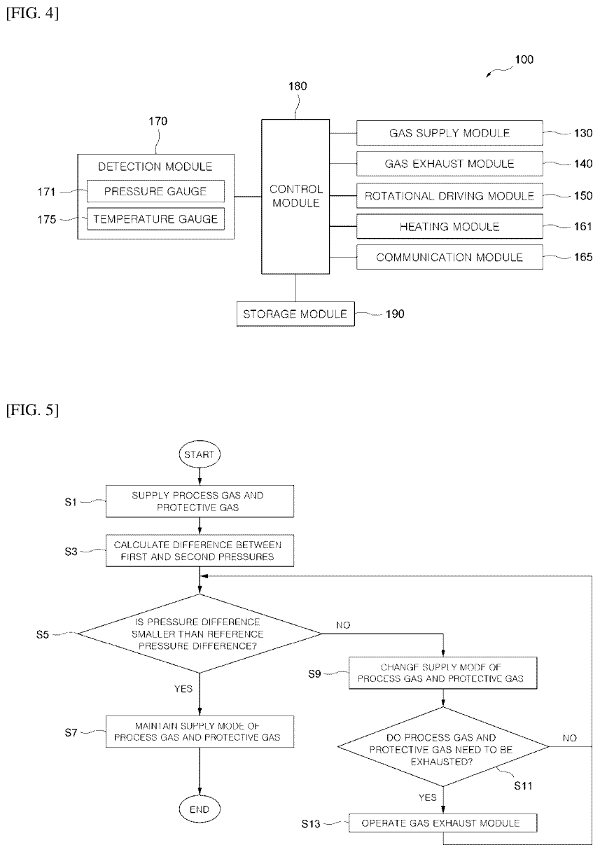

The control configuration of the high-pressure substrate processing apparatus 100 is described with reference to FIG. 4. FIG. 4 is a block diagram illustrating a control configuration of the high-pressure substrate processing apparatus 100 of FIG. 1.

Referring to this drawing (and FIGS. 1 to 3), the high-pressure substrate processing apparatus 100 may further include a heating module 161, a communication module 165, a detection module 170, a control module 180, and a storage module 190, in addition to the gas supply module 130, the gas exhaust module 140, and the rotational driving module 150 described above.

The heating module 161 includes the above-described heater. The heater may be considered a component of the second chamber 120, but may also be classified as a separate component, the heating module 161, as illustrated in this drawing. The heating module 161, specifically the heater, is disposed within the second chamber 120 so as to be directed toward the first chamber 110.

The communication module 165 is a component that allows the communication between the reaction space and the protective space. The communication module 165 may have a communication channel (not illustrated) formed to penetrate through the first chamber 110, specifically the inner door 115. The communication module 165 may also have an opening/closing valve (not illustrated) that opens and closes the communication channel.

The detection unit 170 is a component for detecting the environment of the chambers 110 and 120. The detection unit 170 may include a pressure gauge 171 and a temperature gauge 175. The pressure gauge 171 and the temperature gauge 175 may be installed in each chamber 110 and 120. The pressure gauge 171 may also include a differential gauge for measuring the pressure difference between the first chamber 110 and the second chamber 120.

The control module 180 is a component that controls the gas supply module 130, the gas exhaust module 140, the rotational driving module 150, the heating module 161, and the communication module 165. The control module 180 may control the gas supply module 130, etc., based on the detection results of the detection module 170.

The storage module 190 is a component that stores data, programs, etc., that the control module 180 may reference for control.

According to this configuration, the control module 180 may control the operation of the gas supply module 130 based on the pressure of the chambers 110 and 120 obtained through the pressure gauge 171. According to the operation of the gas supply module 130, the inner chamber 110 is filled with the reaction gas at the first pressure. The outer chamber 120 is filled with the protective gas at the second pressure. The control module 180 controls the pressure difference between the first and second pressures to be smaller than the maximum allowable pressure difference of the sealing unit 155.

The control module 180 may also control the operation of the gas exhaust module 140 based on the pressure of the chambers 110 and 120 obtained through the pressure gauge 171. According to the operation of the gas exhaust module 140, the reaction gas may be exhausted from the inner chamber 110. The protective gas may be exhausted from the outer chamber 120. The control module 180 may use the gas exhaust module 140 to control the first and second pressures in relation to the maximum allowable pressure difference.

The control module 180 may control the rotational driving module 150 differently depending on the first pressure. Specifically, the control module 180 may adjust the rotational power depending on the magnitude of the first pressure.

The control module 180 may control the operation of the heating module 161 based on the temperature of the chamber 110 and 120 obtained through the temperature gauge 175. The reaction gas may reach the reaction temperature depending on the operation of the heating module 161.

The control module 180 may also open the opening/closing valve to allow the communication between the reaction space and the protective space. In this case, the pressure difference between the first and second pressures is eliminated.

FIG. 5 is a flowchart for describing an operation of the high-pressure substrate processing apparatus 100 according to another embodiment of the present disclosure.

Referring further to this drawing, the control module 180 controls the gas supply module 130 to supply the reaction gas and the protective gas to the chambers 110 and 120 (S1).

The control module 180 controls the pressure gauge 171 to calculate the pressure difference between the first and second pressures (S3). The differential pressure gauge may be utilized to calculate the pressure difference between the first and second pressures.

The control module 180 determines whether the calculated pressure difference is smaller than a reference pressure difference (S5). The reference pressure difference is a value set to be smaller than the maximum allowable pressure difference, taking into account a safety factor. For example, when the maximum allowable pressure difference is 14 psi, the reference pressure difference may be set to 10 psi or 12 psi.

When the pressure difference is smaller than the reference pressure difference, the control module 180 maintains a supply mode for the reaction gas and the protective gas (S7).

On the other hand, when the pressure difference is higher than the reference pressure difference, the control module 180 operates to reduce the pressure difference. The control module 180 may control the gas supply module 130 to change the supply mode for the reaction gas and the protective gas (S9). Specifically, the pressure difference may be reduced by lowering the supply flow rate of the protective gas or increasing the supply flow rate of the reaction gas.

The control module 180 determines whether it is also necessary to control the gas exhaust module 140 to reduce the pressure difference (S11). For example, when it is difficult to additionally supply the reaction gas to the first chamber 110, controlling the gas exhaust module 140 may be an alternative.

The control module 180 controls the gas exhaust module 140 when necessary to reduce the pressure difference (S13). Specifically, the control module 180 may selectively open the exhaust pipes 141 and 145 (see FIG. 1) to lower the first pressure or the second pressure.

Through this control, the pressure difference is maintained smaller than the reference pressure difference. This makes it possible to prevent the sealing unit 155 from being damaged due to the pressure difference exceeding the reference pressure difference and, furthermore, the maximum allowable pressure difference. When the sealing unit 155 is damaged, the reaction space and the protective space communicate with each other due to the gap, so the pressure difference may no longer be maintained. For this reason, the maximum allowable pressure difference for normal operation of the rotational driving module 150 may be determined by the maximum allowable pressure difference of the sealing unit 155.

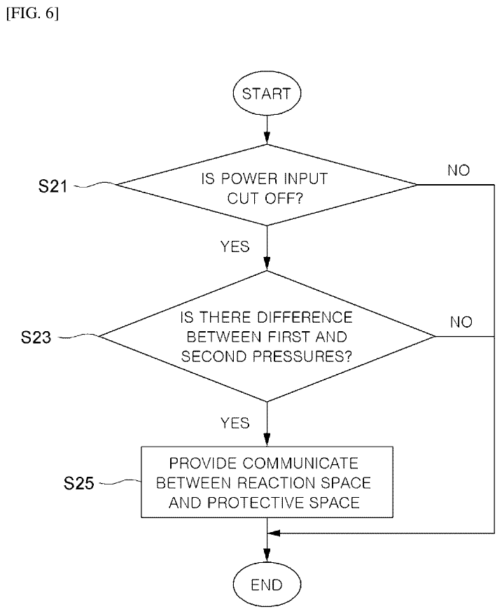

FIG. 6 is a flowchart for describing the operation of the high-pressure substrate processing apparatus 100 according to another embodiment of the present disclosure.

Referring further reference to this drawing, the power input to the high-pressure substrate processing apparatus 100 may be cut off (S21). The power input cutoff may occur in the event of a power outage, etc.

The control module 180 may operate to prevent damage to the sealing unit 155 in the event of the power input cutoff. Specifically, the control module 180 determines whether the pressure difference exists in the event of the power input cutoff (S23).

When the pressure difference exists, the control module 180 allows the communication between the reaction space and the protective space (S25). Specifically, the control module 180 operates the opening/closing valve to open the communication channel. As the communication channel is open, the reaction space and the protective space communicates with each other, thereby eliminating the pressure difference between the first and second pressures.

While the high-pressure substrate processing apparatus 100 described herein is exemplified as a batch-type processing apparatus, the present disclosure is not limited thereto. The present disclosure may also be applied to a single wafer type processing apparatus.

### INDUSTRIAL APPLICABILITY

The present disclosure has industrial applicability in the field of manufacturing the high-pressure substrate processing apparatus.

1. A high-pressure substrate processing apparatus, comprising:
an inner chamber having a reaction space in which a substrate to be processed is disposed;
an outer chamber disposed so as to accommodate the inner chamber;
a gas supply module configured to supply a reaction gas for processing the substrate to be processed to the reaction space at a first pressure higher than the atmospheric pressure, and to supply a protective gas to a protective space between the outer chamber and the inner chamber at a second pressure set in relation to the first pressure;
a rotational driving module including a power generating unit for generating rotational power, a power transmission unit formed to transmit the rotational power to the substrate to be processed such that the substrate to be processed rotates, and a sealing unit for sealing a gap between the inner chamber and the power transmission unit, the sealing unit being affected by a pressure difference between the first and second pressures; and
a control module configured to control the gas supply module so as to maintain the pressure difference between the first and second pressures to be smaller than a maximum allowable pressure difference of the sealing unit.

2. The high-pressure substrate processing apparatus of claim 1, wherein the control module operates to reduce the pressure difference between the first and second pressures when the pressure difference between the first and second pressures exceeds a reference pressure difference smaller than the maximum allowable pressure difference.

3. The high-pressure substrate processing apparatus of claim 2, further comprising:
a gas exhaust module configured to exhaust the reaction gas from the reaction space and the protective gas from the protective space,
wherein the control module operates at least one of the gas supply module and the gas exhaust module to reduce the pressure difference between the first and second pressures.

4. The high-pressure substrate processing apparatus of claim 1, wherein, when power is cut off, the control module allows communication between the reaction space and the protective space to eliminate the pressure difference between the first and second pressures.

5. The high-pressure substrate processing apparatus of claim 1, wherein the control module controls the power generating unit so that a magnitude of the rotational power varies depending on a magnitude of the first pressure.

6. The high-pressure substrate processing apparatus of claim 1, wherein the inner chamber further includes:
an inner housing; and
an inner door defining the reaction space together with the inner housing, and
the control module controls the rotational driving module so that a boat rotates during movement of the inner door away from the inner housing.

7. The high-pressure substrate processing apparatus of claim 1, wherein the first pressure ranges from a few to several tens of atm, and
the second pressure is higher than the atmospheric pressure.

8. A high-pressure substrate processing apparatus, comprising:
an inner chamber having a reaction space in which a substrate to be processed is disposed;
an outer chamber disposed so as to accommodate the inner chamber;
a gas supply module configured to supply a reaction gas for processing the substrate to be processed to the reaction space at a first pressure higher than the atmospheric pressure, and to supply a protective gas to a protective space between the outer chamber and the inner chamber at a second pressure set in relation to the first pressure; and
a rotational driving module extending from the protective space into the reaction space, affected by a pressure difference between the first and second pressures, and configured to rotate and drive the substrate to be processed disposed in the reaction space.

9. The high-pressure substrate processing apparatus of claim 8, wherein the inner chamber further includes a boat disposed in the reaction space and onto which the substrate to be processed is loaded, and
the rotational driving module includes:
a power generating unit disposed in the protective space and configured to generate rotational power; and
a power transmission unit linking the power generating unit to the boat to allow the boat to rotate by receiving the rotational power.

10. The high-pressure substrate processing apparatus of claim 9, wherein the power generating unit includes a motor-driven actuator, and
the power transmission unit includes a transmission shaft connected to the power generating unit and penetrating through the inner chamber to be coupled to the boat.

11. The high-pressure substrate processing apparatus of claim 9, wherein the rotational driving module further includes a sealing unit that seals a gap between the power transmission unit and the inner chamber, and
the sealing unit has a maximum allowable pressure difference higher than the pressure difference between the first and second pressures.

12. The high-pressure substrate processing apparatus of claim 8, wherein the inner chamber further includes:
an inner housing forming the reaction space; and
an inner door configured to open and close the reaction space, and
the rotational driving module is mounted on the inner door.

13. The high-pressure substrate processing apparatus of claim 12, wherein the outer chamber includes an outer door positioned to face the inner door, and
the rotational driving module is disposed spaced apart from the outer door to allow the outer door to move toward the inner door.
